(19) United States
(12) Patent Application Publication
(10) Pub. No.: US 2005/0194641 A1
(43) Pub. Date: Sep. 8, 2005

(54) Thin film transistor and method for manufacturing the same

(75) Inventors: Chien-Ting Lai, Miao-Li (TW); Jia-Pang Pang, Miao-Li (TW); Yung-Chang Chen, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/074,528

(22) Filed: Mar. 7, 2005

(30) Foreign Application Priority Data
Mar. 5, 2004 (TW) 93105801

(51) Int. Cl. H01L 27/01; H01L 21/00

(52) U.S. Cl. 257/347; 438/149

(57) ABSTRACT

A simplified method for forming a TFT includes four photolithographic processes. A first photolithographic process is used for forming a gate electrode (42). A second photolithographic process is used for forming a source electrode (742), a drain electrode (741), a channel layer (82), a source ohmic contact layer (832), and a drain ohmic contact layer (831). A third photolithographic process is used for forming a passivation layer (110). A fourth photolithographic process is used for finally forming a pixel electrode (120). The source electrode and the drain electrode are made of molybdenum or a molybdenum alloy.

### BACKGROUND OF THE INVENTION

1. Field of the Invention

The present invention relates to thin film transistors (TFTs); and particularly to a thin film transistor typically used in a liquid crystal display (LCD) and a method for manufacturing the thin film transistor.

2. Description of Related Art

Generally, a conventional bottom gate type TFT used in an LCD includes a substrate, a gate electrode formed on the substrate, a gate insulation layer formed on the gate electrode, an amorphous silicon (a-Si) layer formed on the gate insulation layer, two impurity-doped a-Si layers formed on two ends of the a-Si layer respectively, a source electrode formed on one impurity-doped a-Si layer and the gate insulation layer, and a drain electrode formed on another one impurity-doped a-Si layer and the gate insulation layer.

Referring to FIG. 13, a conventional method of manufacturing a bottom gate type TFT includes the steps of:
step 10: providing an insulating substrate, and coating a gate metal layer and a first photo-resist layer in that order on the insulating substrate;
step 11: forming a gate electrode by a first photolithographic process, which includes etching the gate metal layer and wiping off the first photo-resist layer;
step 12: coating a gate insulation layer, an a-Si layer, an impurity-doped a-Si layer and a second photo-resist layer in that order on the gate electrode;
step 13: forming a channel layer, a source ohmic contact layer and a drain ohmic contact layer by a second photolithographic process, which includes etching the a-Si layer and the impurity-doped a-Si layer, and wiping off the second photo-resist layer;
step 14: coating a metal layer for source and drain electrodes on the above-described structure, and a third photo-resist layer on the insulating substrate and the impurity-doped a-Si pattern;
step 15: forming a source electrode and a drain electrode by a third photolithographic process, which includes etching the metal layer for the source and drain electrodes and wiping off the third photo-resist layer;
step 16: forming a resin layer for a passivation layer and a fourth photo-resist layer on the above-described structure;
step 17: forming the passivation layer by a fourth photolithographic process, which includes etching the passivation layer and wipping off the fourth photo-resist layer;
step 18: coating an electrically conductive layer and a fifth photo-resist layer on the above-described structure;
step 19: forming a pixel electrode by a fifth photolithographic process which includes etching the electrically conductive layer and wiping off the fifth photo-resist layer.

The above-described method includes five photolithographic processes. Each photolithographic process includes photolithography, etching, and wiping off photo-resist layers. Generally, the photolithographic process is complicated, and the cost is expensive. Therefore, to simplify the method and reduce the cost of the manufacturing a TFT, a method with fewer photolithographic processes is desired.

The source/drain electrodes are usually a single layer of chromium (Cr), multi-layers of molybdenum/aluminum/titanium (Mo/Al/Ti), or multi-layers of Ti/Al/Ti. Because Cr is generally only wet-etched, and the impurity-doped a-Si layer can be dry-etched or wet-etched, wet-etching is preferred to simply the manufacturing method. However, wet-etching different layers usually requires different liquors to be used. That is, the etching conditions are always changed during the manufacturing process. Hence, the manufacturing process is complex, and the yield is prone to be low.

Further, the process of etching Al needs chlorine (Cl₂), and residual chlorine reacts with water in the atmosphere to produce hydrogen chloride (HCl). The hydrogen chloride is caustic, and may decay the TFT. This phenomenon is known as Al-corrosion, and also contributes to low yield.

It is desired to provide a method for manufacturing a TFT which overcomes the above-described problems.

### SUMMARY OF THE INVENTION

In one embodiment of the present invention, a method for manufacturing a TFT includes the steps of:
providing an insulating substrate, and coating a gate metal layer on the insulating substrate;
forming a gate electrode through a first photolithographic process;
coating a gate insulation layer, an a-Si layer, an impurity-doped a-Si layer, and a metal layer in the order on the gate electrode and the insulating substrate;
forming a source electrode, a drain electrode, a source ohmic contact layer and a drain contact layer through a second photolithographic process;
coating a resin layer on the hitherto-formed structure;
forming a passivation layer through a third photolithographic process;
coating an electrically conductive layer on the hitherto-formed structure; and
forming a pixel electrode through a fourth photolithographic process.

In the earlier-described conventional method for manufacturing a TFT, forming source and drain electrodes, and forming a channel layer, a source ohmic contact layer and a drain contact layer must involve different photolithographic processes. In other words, in the conventional method, at least two photolithographic processes must be employed to produce the source and drain electrodes, the channel layer and the source and drain ohmic contact layers. In contrast, in the method of the present invention, the source and drain electrodes, the channel layer, and the source and drain ohmic contact layers are produced by the same one photolithographic process. Therefore the number of photolithographic processes can be reduced in the method of the present invention. Compared to the conventional method of forming a TFT, the method of the present invention is simpler.

Other objects, advantages and novel features of the invention will become more apparent from the following detailed description when taken in conjunction with the accompanying drawings; in which:

### BRIEF DESCRIPTION OF THE DRAWINGS

FIG. 1 is a schematic, cross-sectional view of a TFT according to the present invention;

FIG. 2 is a flow chart of a method for manufacturing the TFT of FIG. 1;

FIGS. 3 and 4 are cross-sectional views relating to a first photolithographic process used in the method of FIG. 2;

FIG. 5 through FIG. 10 are cross-sectional views relating to a second photolithographic process used in the method of FIG. 2;

FIGS. 11 and 12 are cross-sectional views relating to a third photolithographic process used in the method of FIG. 2; and

FIG. 13 is a flow chart of a conventional method of manufacturing a TFT.

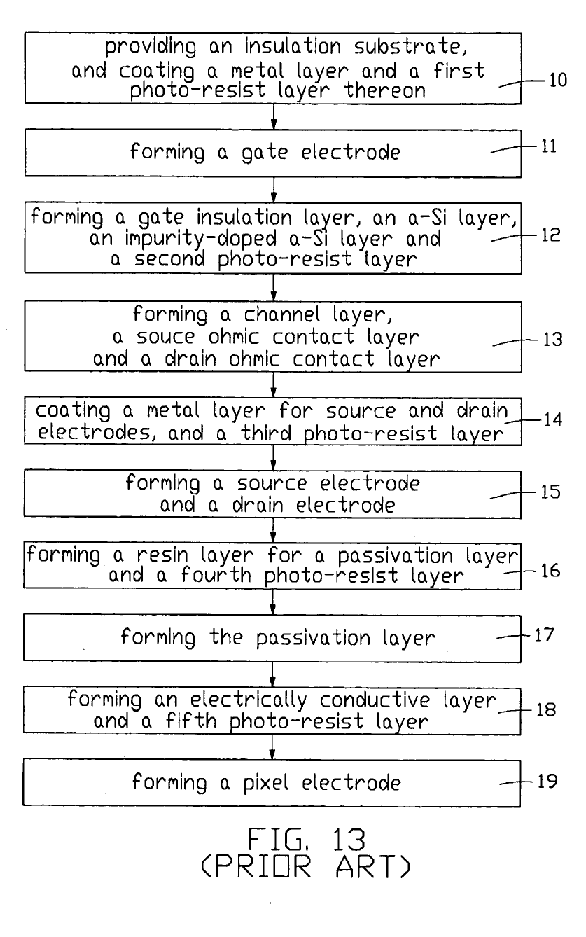

### DETAILED DESCRIPTION OF THE EMBODIMENTS

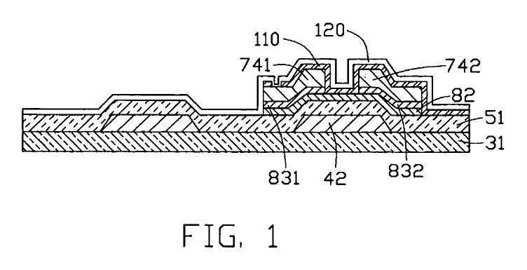

Referring to FIG. 1, this is a cross-sectional view of a TFT according to the present invention. The TFT includes an insulating substrate 31, a gate electrode 42 disposed on the insulating substrate 31, a gate insulation layer 51 covering the insulating substrate 31 and the gate electrode 42, a channel layer 82 disposed on the gate insulation layer 51, a source ohmic contact layer 832 and a drain ohmic contact layer 831 arranged on two ends of the channel layer 82 respectively, a source electrode 742 disposed on the source ohmic contact layer 832, and a drain electrode 741 disposed on the drain ohmic contact layer 831. In addition, a passivation layer 110 is coated on the source electrode 742, the drain electrode 741 and the channel layer 82, and a pixel electrode 120 is covered on the passivation layer 110 and the gate insulation layer 51.

The insulating substrate 31 may be made of glass, quartz, or ceramic. The source electrode 742 and the drain electrode 741 are made of molybdenum or a molybdenum alloy. The molybdenum alloy is normally a molybdenum-tungsten (Mo—W) alloy or a molybdenum-niobium (Mo—Nb) alloy. In the molybdenum-tungsten alloy, a mass ratio of molybdenum to tungsten is 9:1. In the molybdenum-niobium alloy, a mass ratio of molybdenum to niobium is 9:1.

The electrical resistance of molybdenum is 12˜13 mΩ×cm. The resistance of molybdenum-tungsten is 13˜14 mΩ×cm. The resistance of molybdenum-niobium is 15˜17 mΩ×cm. The resistance of chromium is 20˜22 mΩ×cm. The resistance of molybdenum or a molybdenum alloy is clearly less than that of chromium. Compared with the conventional TFT having the source electrode and the drain electrode made of chromium, the source electrode 742 and the drain electrode 741 have a lower resistance. Consequently, the TFT according to the present invention has a lower power consumption compared with the conventional TFT. In a word, the electrical characteristic of the TFT according to the present invention is better than that of the conventional TFT.

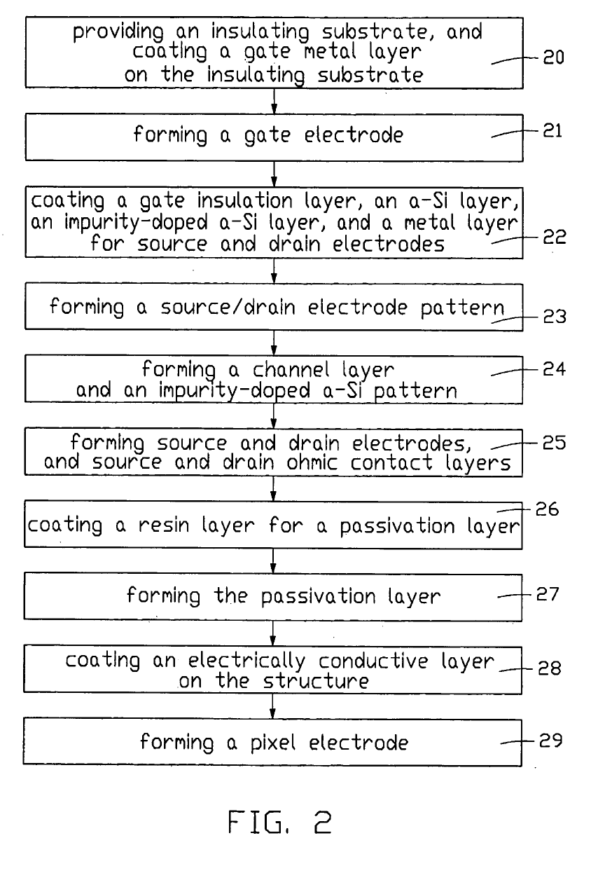

The present invention further discloses a method of forming the above-described TFT. Referring to FIG. 2, the method mainly includes the following steps:
step 20: providing the insulating substrate 31 and coating a gate metal layer on the insulating substrate 31;
step 21: forming the gate electrode 42;
step 22: coating the gate insulation layer 51, an a-Si layer, an impurity-doped a-Si layer, and a metal layer for the source and the drain electrodes 742, 741 on the gate electrode 42 and the insulating substrate 31, in that order from bottom to top,
step 23: forming a source and a drain patterns;
step 24: forming a channel layer 82, and an impurity-doped a-Si pattern;
step 25: forming the source electrode 742, the drain electrode 741, the source ohmic contact layer 832 and the drain ohmic contact layer 831;
step 26: coating a resin layer for the passivation layer 110 on top of the hitherto-formed structure;
step 27: forming the passivation layer 110;
step 28: coating an electrically conductive layer on the hitherto-formed structure; and
step 29: forming a pixel electrode 120.

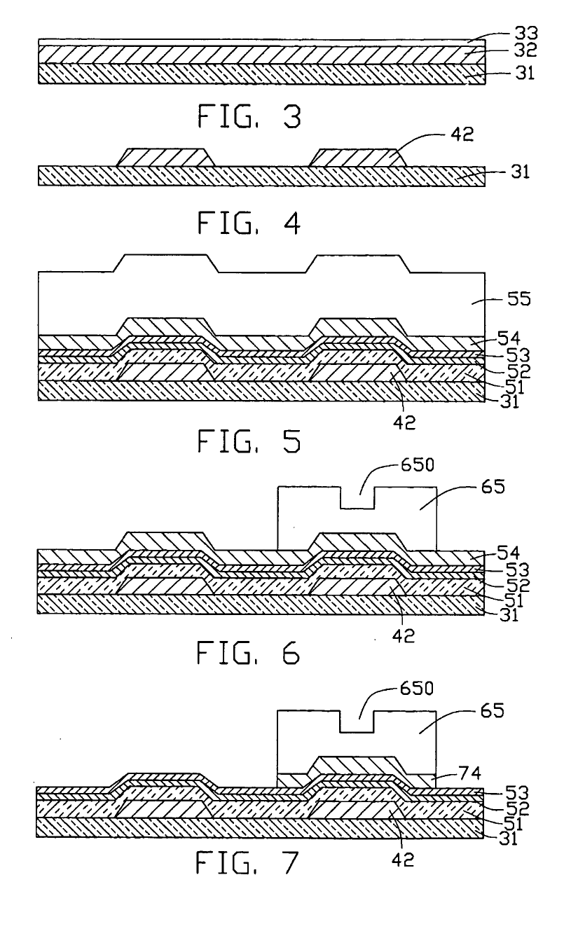

In step 20, referring to FIG. 3, this includes providing the insulating substrate 31, coating a gate metal layer 32 on the insulating substrate 31, and disposing a first photo-resist layer 33 on the gate metal layer 32.

In step 21, referring to FIGS. 3 and 4, the gate electrode 42 is mainly formed by patterning the gate metal layer 32 through a first photolithographic process. Such process includes using a photo mask to collimate the first photo-resist layer 33, using an ultraviolet light to expose the first photo-resist layer 33 and form a predetermined pattern, and then forming the gate electrode 42 by developing the first photo-resist layer 33, wiping off the residual first photo-resist layer 33, etching the gate metal layer 32, and cleaning and baking the insulating substrate 31.

In the first photolithographic process, a material of the gate metal layer 32 may be selected from the group consisting of Cr, Mo, W and thallium (Tl). The ultraviolet light may be replaced by X-rays, an electron beam, or an ion beam. The method of etching the gate metal layer 32 is dry etching or wet etching.

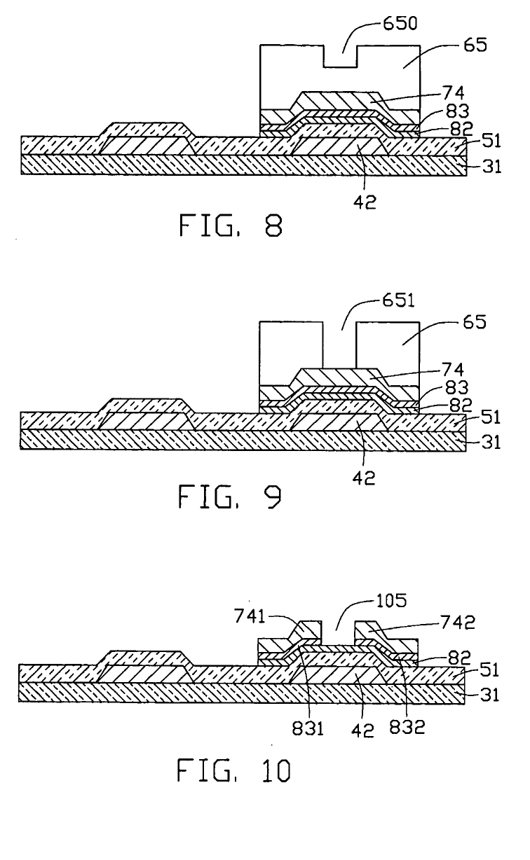

The source electrode 742, the drain electrode 741, the source ohmic contact layer 832 and the drain contact layer 831 are produced by a second photolithographic process, which includes steps 22, 23, 24, and 25. In step 22, referring to FIG. 5, firstly, chemical vapor deposition (CVD) is used to coat the gate insulation layer 51 made of silicon nitride (SiNₓ), wherein the reaction gases are silicon alkyl (SiH₄) and ammonia (NH₃). Secondly, a CVD method is used to coat an a-Si layer 52 on the gate insulation layer 51, wherein the reaction gases are silicon chloride and hydrogen. After that, an impurity-doped a-Si layer 53 is coated on the a-Si layer 52 by doping technology. Lastly, a metal layer 54 is sputtered on the impurity-doped a-Si layer 53 for the source and drain electrodes 742, 741, and a second photo-resist layer 55 is deposited on the metal layer 54.

In step 23, referring to FIGS. 6 and 7, the second photo-resist layer 55 is exposed and developed, and then the residual second photo-resist layer 55 is wiped off to form a photo-resist structure 65 and a concavity 650. The metal layer 54 is wet etched, and a portion of the metal layer 54 which is not covered by the photo-resist structure 65 is wiped off, thereby forming a source/drain electrode pattern 74.

In step 24, referring to FIG. 8, the a-Si layer 52 and the impurity-doped a-Si layer 53 are dry etched, and portions of the a-Si layer 52 and the impurity-doped a-Si layer 53 which are not covered by the source/drain electrode pattern 74 are wiped off, thereby forming the channel layer 82 and an impurity-doped a-Si pattern 83. In the etching steps described in this paragraph, the photo-resist structure 65 is constantly corroded, thereby forming a through hole 651 in a center of the photo-resist structure 65, as shown in FIG. 9.

In step 25, referring to FIGS. 9 and 10, the source/drain electrode pattern 74 and the impurity-doped a-Si pattern 83 are etched, portions of the source/drain electrode pattern 74 and the impurity-doped a-Si pattern 83 corresponding to the through hole 651 are wiped off. Consequently, a concave 105, the source and drain electrodes 742, 741, and the source and drain ohmic contact layers 832, 831 are formed.

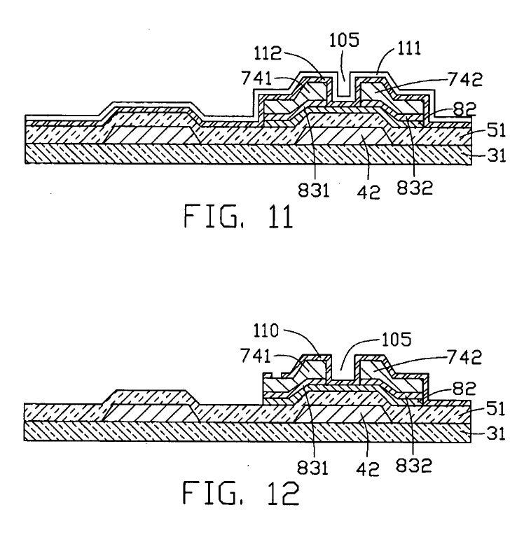

In step 26, referring to FIG. 11, a resin layer 112 is coated on the gate insulation layer 51, the source and drain electrodes 742, 741, and the channel layer 82. Then a third photo-resist layer 111 is formed on the resin layer 112.

In step 27, referring to FIG. 12, the passivation layer 110 is produced by a third photolithographic process. This process includes using an ultraviolet light to illuminate the third photo-resist layer 111 through a photo mask with a predetermined pattern and forming the predetermined pattern on the third photo-resist layer 111, and etching the resin layer 112 corresponding to the predetermined pattern and wiping off the residual third photo-resist layer 111, thereby obtaining the passivation layer 110.

Referring to FIGS. 1 and 12, the pixel electrode 120 is produced by a fourth photolithographic process, which includes steps 28 and 29. The fourth photolithographic process is very similar to the third photolithographic process. In step 28, an electrically conductive layer (not shown) and a fourth photo-resist layer (not shown) are formed. In step 29, the fourth photo-resist layer is developed, the residual photo-resist layer is wiped off, and the electrically conductive layer is etched, thereby forming the pixel electrode 120.

In the earlier-described conventional method of manufacturing a TFT, forming source and drain electrodes, and forming a channel layer, a source ohmic contact layer and a drain contact layer must involve different photolithographic processes. In other words, in the conventional method, at least two photolithographic processes must be employed to produce the source and drain electrodes, the channel layer and the source and drain ohmic contact layers. In contrast, in the method of the present invention, the source and drain electrodes 742, 741, the channel layer 82, and the source and drain ohmic contact layers 832, 831 are formed by the same photolithographic process. Therefore the number of photolithographic processes can be reduced in the method of the present invention.

In addition, in the method of the present invention, a material of the metal layer 54 for the source and drain electrodes 742, 741 may be molybdenum or a molybdenum alloy. Because the metal layer 54 made of molybdenum or a molybdenum alloy may be etched by dry etching or wet etching, and the a-Si layer 52 and the impurity-doped a-Si layer 53 are etched by dry etching, the metal layer 54, the a-Si layer 52 and the impurity-doped a-Si layer 53 can be etched in the same action using the same equipment. In the process of etching the metal layer 54, the a-Si layer 52 and the impurity-doped a-Si layer 53, only the associated gases need to be changed. Therefore, the etching process is simplified. In a word, compared to the conventional method for forming a TFT, the method of the present invention is simpler.

Furthermore, the method of the present invention uses molybdenum or a molybdenum alloy instead of aluminum to provide the metal layer 54 for the source and drain electrodes 742, 741. Therefore Al corrosion is avoided.

It is to be understood, however, that even though numerous characteristics and advantages of the present invention have been set out in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A thin film transistor, comprising:
an insulating substrate;
a gate electrode arranged on the insulating substrate;
a gate insulation layer formed on the gate electrode;
a channel layer arranged on the gate insulation layer;
a source ohmic contact layer and a drain ohmic contact layer arranged on two ends of the channel layer respectively;
a source electrode arranged on the source ohmic contact layer;
a drain electrode arranged on the drain ohmic contact layer; and
a material of each of the source and drain electrodes is selected from the group consisting of molybdenum and a molybdenum alloy.

2. The thin film transistor according to claim 1, wherein the molybdenum alloy is a molybdenum-tungsten alloy or a molybdenum-niobium alloy.

3. The thin film transistor according to claim 2, wherein a mass ratio of molybdenum and tungsten in the molybdenum-tungsten alloy is 9:1.

4. The thin film transistor according to claim 2, wherein a mass ratio of molybdenum and niobium in the molybdenum-niobium alloy is 9:1.

5. A method for manufacturing a thin film transistor, comprising the steps of:
providing an insulating substrate, and coating a gate metal layer on the insulating substrate;
forming a gate electrode on the insulating substrate through a first photolithographic process;
coating a gate insulation layer, an a-Si layer, an impurity-doped a-Si layer, and a metal layer in the order on the gate electrode and the insulating substrate;
forming a source electrode, a drain electrode, a source ohmic contact layer and a drain contact layer through a second photolithographic process;
coating a resin layer on the hitherto-formed structure;
forming a passivation layer through a third photolithographic process;
coating an electrically conductive layer on the hitherto-formed structure; and
forming a pixel electrode through a fourth photolithographic process.

6. The method according to claim 5, wherein the second photolithographic process includes forming source and drain patterns, a channel layer and an impurity-doped amorphous-silicon pattern.

7. The method according to claim 5, wherein the source and drain electrodes are made of molybdenum.

8. The method according to claim 5, wherein the source and drain electrodes are made of a molybdenum alloy.

9. The method according to claim 8, wherein the molybdenum alloy is a molybdenum-tungsten alloy or a molybdenum-niobium alloy.

10. The method according to claim 9, wherein a mass ratio of molybdenum and tungsten in the molybdenum-tungsten alloy is 9:1.

11. The method according to claim 9, wherein a mass ratio of molybdenum and niobium in the molybdenum-niobium alloy is 9:1.

12. A method of making a thin film transistor comprising steps in sequence:
providing an insulating substrate;
coating a gate metal layer on the insulating substrate;
forming a gate electrode;
coating a gate insulation layer and a metal layer for source and drain electrodes;
forming a source/drain electrode pattern;
forming a channel layer;
forming source and drain electrodes, and source and drain ohmic contact layers;
coating a resin layer for a passivation layer; and
forming a passivation layer.
